(19) United States
(12) Patent Application Publication
(10) Pub. No.: US 2002/0021178 A1
(43) Pub. Date: Feb. 21, 2002

(54) PHASE-LOCKED LOOP CIRCUIT HAVING RATE-OF-CHANGE DETECTOR

(76) Inventor: Toshiro Yoshida, Tokyo (JP)

Correspondence Address: MCGINN & GIBB, PLLC, 8321 OLD COURTHOUSE ROAD, SUITE 200, VIENNA, VA, 22182-3817, US

(21) Appl. No.: 09/512,351

(22) Filed: Feb. 24, 2000

(30) Foreign Application Priority Data
Feb. 25, 1999 (JP) 047689/1999

(51) Int. Cl. H03L 7/107

(52) U.S. Cl. 331/17; 331/DIG. 2

(57) ABSTRACT

A phase-locked loop circuit includes a phase comparator, a filter circuit, a voltage-controlled oscillator, a pull-out state detection circuit, and an FET switch. The phase comparator receives input data and a reference signal and outputs a voltage value representing a phase difference between the input data and the reference signal. The filter circuit generates and outputs a control voltage on the basis of the voltage value representing the phase difference between the input data and the reference signal output from the phase comparator. The voltage-controlled oscillator generates the reference signal on the basis of the control voltage output from the filter circuit and outputs the reference signal to the phase comparator. The pull-out state detection circuit outputs a signal representing a pull-out state when a change amount of the control voltage output from the filter circuit within a predetermined time exceeds a threshold value. The FET switch short-circuits at least one of constituent elements of the filter circuit when the signal representing the pull-out state is output from the pull-out state detection circuit.

### BACKGROUND OF THE INVENTION

The present invention relates to a phase-locked loop circuit (to be referred to as a PLL circuit hereinafter) and, more particularly, to a PLL circuit which increases the damping factor of a loop filter in a pull-out state to realize high-speed PLL pull-in.

A PLL circuit is a circuit in which a phase comparator (or phase detector) and voltage-controlled oscillator (to be referred to as a VCO hereinafter) construct a feedback loop through a loop filter.

In the PLL circuit, when input data and a reference signal output from the VCO are out of phase (pull-out), the phase comparator generates a voltage value representing the phase difference between the input data and the reference signal and outputs the voltage value to the loop filter. On the basis of the voltage value output from the phase comparator, the loop filter generates a control voltage and feeds it back to the VCO. The oscillation frequency of the reference signal of the VCO changes in accordance with the control voltage fed back from the loop filter so the input data and reference signal are in phase (this state is called “lock”: “phase-locked state”). Once the locked state is established, the oscillation frequency (phase) of the PLL circuit changes following the reference signal even when it largely changes.

The PLL circuit uses the VCO whose oscillation frequency can be changed in accordance with the control voltage and is therefore used as a frequency synthesizer for accurately oscillating many signals with different frequencies in, e.g., a multi-channel transceiver.

In a pull-out state, the frequency synthesizer must quickly lock the frequency (phase) with the reference signal for the application purpose of the PLL circuit for stabilizing the oscillation frequency.

In a method proposed in Japanese Patent Laid-Open No. 59-156029 (reference 1), as shown in FIG. 4, diodes D1 and D2 directed in different directions are connected in parallel to a resistor R1 connected between the input and output of a loop filter. In the pull-out state, one of the diodes D1 and D2 is turned on to increase the damping factor of a lag-lead filter 4 as a loop filter, thereby realizing high-speed PLL pull-in.

However, this prior art has the following problems.

In the method disclosed in reference 1, let Vf be the ON voltage in the forward direction of the diodes D1 and D2. When the potential difference across the resistor R1 shown in FIG. 4 does not exceed the ON voltage Vf, the diodes D1 and D2 are not turned on.

Hence, as shown in FIG. 2, when the output voltage of a phase comparator 2 varies between −Vf and Vf, the diodes D1 and D2 are not turned on, and a time constant equivalently represented by R1*C1 cannot be made small. Since the damping factor cannot be large, the time required for PLL pull-in cannot be shortened.

Additionally, the method disclosed in reference 1 cannot be applied to a phase comparator which outputs phase lag/lead information as “H” or “L”, as shown in FIG. 3.

Furthermore, the method disclosed in reference 1 has no means for detecting the pull-out state although the pull-out state must be detected to know the lock state of the circuit.

### SUMMARY OF THE INVENTION

The present invention has been made in consideration of the above situation, and has as its first object to provide a PLL circuit which realizes high-speed PLL pull-in independently of the waveform or magnitude of an output voltage of a phase comparator.

It is the second object of the present invention to provide a PLL circuit having a means for detecting a pull-out state.

In order to achieve the above objects, according to the present invention, there is provided a phase-locked loop circuit comprising a phase comparator for receiving input data and a reference signal and outputting a voltage value representing a phase difference between the input data and the reference signal, a filter circuit for generating and outputting a control voltage on the basis of the voltage value representing the phase difference between the input data and the reference signal output from the phase comparator, a voltage-controlled oscillator for generating the reference signal on the basis of the control voltage output from the filter circuit and outputting the reference signal to the phase comparator, pull-out state detection means for outputting a signal representing a pull-out state when a change amount of the control voltage output from the filter circuit within a predetermined time exceeds a threshold value, and short-circuit means for short-circuiting at least one of constituent elements of the filter circuit when the signal representing the pull-out state is output from the pull-out state detection means.

### BRIEF DESCRIPTION OF THE DRAWINGS

FIG. 1 is an electrical circuit diagram showing the circuit arrangement of the first embodiment of the present invention;

FIG. 2 is a graph showing the output voltage of a phase comparator with which a PLL circuit of the present invention shown in FIG. 1 can cope;

FIG. 3 is a graph showing the output voltage of the phase comparator with which the PLL circuit of the present invention shown in FIG. 1 can cope;

FIG. 4 is an electrical circuit diagram showing the circuit arrangement of a conventional PLL circuit; and

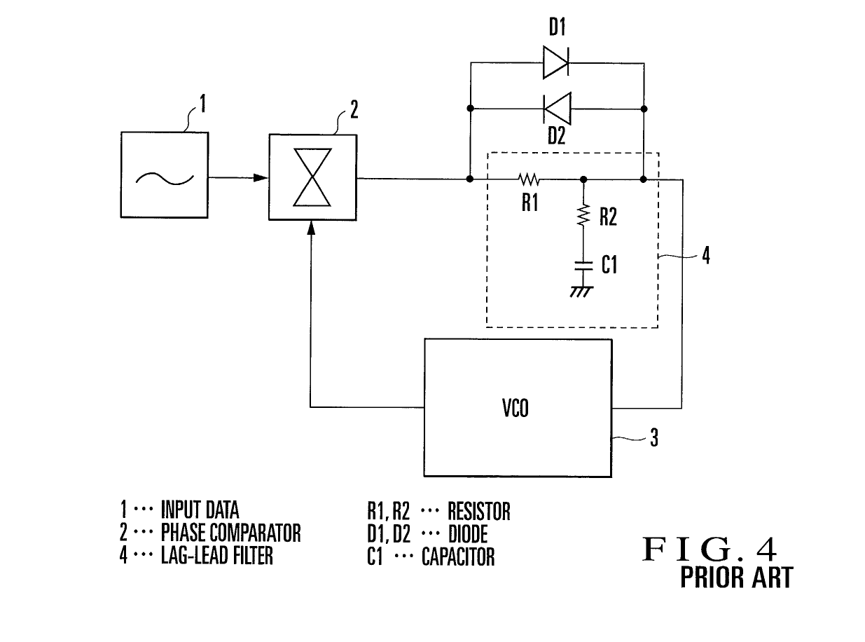

FIG. 5 is an electrical circuit diagram showing the circuit arrangement of a control circuit shown in FIG. 1.

### DESCRIPTION OF THE PREFERRED EMBODIMENT

An embodiment of the present invention will be described below in detail with reference to the accompanying drawings.

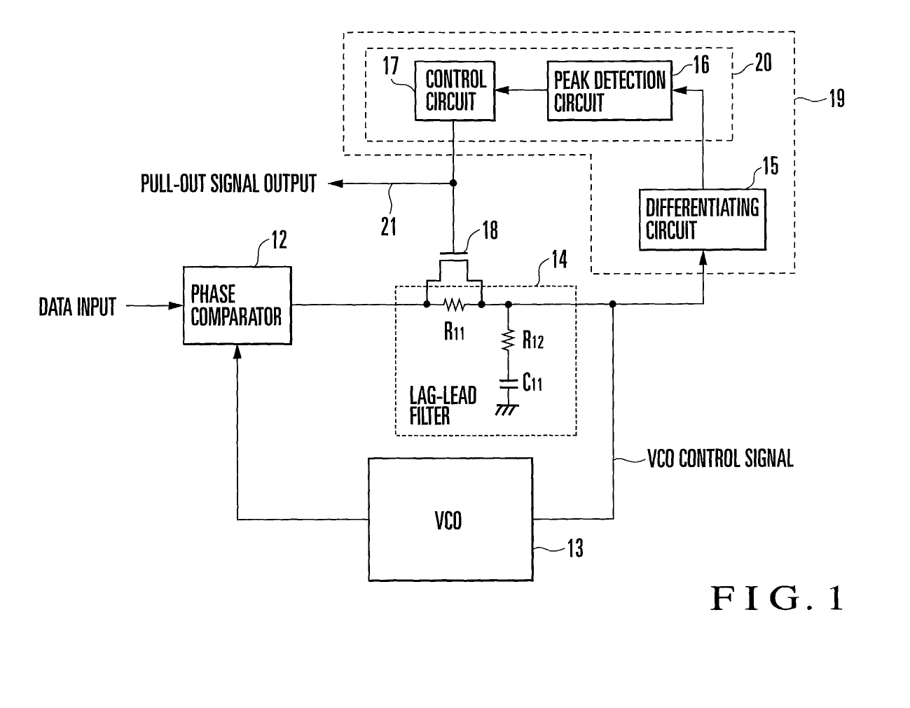

As shown in FIG. 1, the first embodiment of the present invention comprises a phase comparator 12 for detecting the phase difference between input data and a reference signal input from a VCO 13 and outputting a voltage value corresponding to the difference, a lag-lead filter 14 for receiving the output voltage from the phase comparator 12 and generating and outputting the control voltage of the VCO 13, an FET (Field Effect Transistor) switch 18 for short-circuiting the constituent elements of the lag-lead filter 14, the VCO 13 which changes the oscillation frequency of the reference signal output in accordance with the control voltage input from the lag-lead filter 14, a differentiating circuit 15 for detecting a temporal change in control voltage of the VCO 13, a peak detection circuit 16 for detecting the peak of the output result from the differentiating circuit 15 and holding the value, and a control circuit 17 for ON/OFF-controlling the FET switch 18 in accordance with the output signal from the peak detection circuit 16.

In this case, the phase comparator 12 has two input terminals and one output terminal. One input terminal is connected to the signal line of input data, and the other input terminal is connected to the output terminal of the VCO 13. The output terminal of the phase comparator 12 is connected to the input terminal of the lag-lead filter 14. The output terminal of the lag-lead filter 14 is connected to the input terminal of the VCO 13 and the input terminal of the differentiating circuit 15. The output terminal of the differentiating circuit 15 is connected to the input terminal of the peak detection circuit 16. The output terminal of the peak detection circuit 16 is connected to the input terminal of the control circuit 17. The output terminal of the control circuit 17 is connected to the gate of the FET switch 18 and a pull-out signal output line 21. The lag-lead filter 14 determines the loop characteristics of the PLL circuit and is constituted by resistors R11 and R12 and capacitor C11. In this case, the resistor R11 is connected to the input and output of the lag-lead filter 14. The resistor R12 is connected to the output of the lag-lead filter 14 and the capacitor C11. The capacitor C11 is connected to ground. The FET switch 18 has a source connected to the input side of the resistor R11 and a drain connected to the output side of the resistor R11.

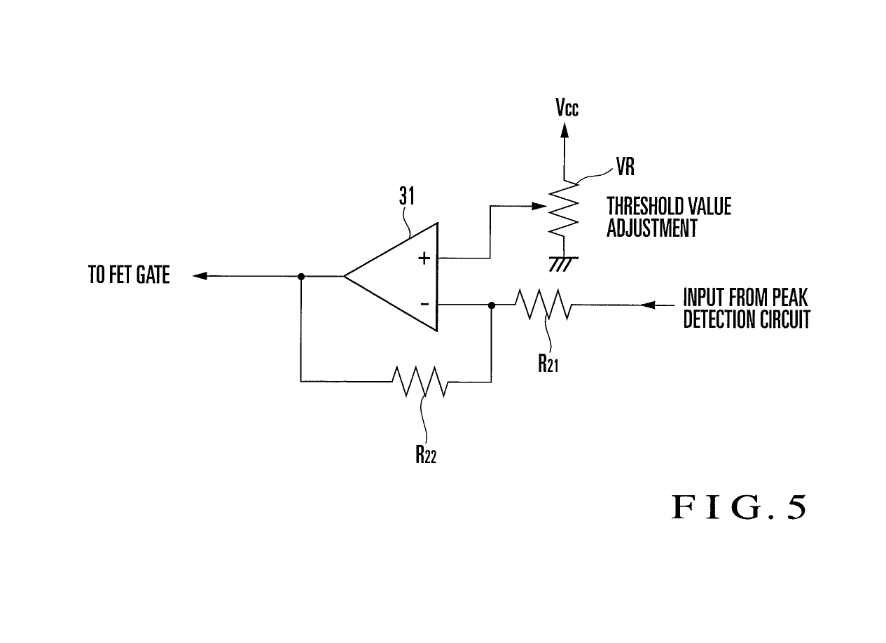

The control circuit 17 is a voltage comparator which outputs a signal representing a pull-out state when the voltage value of the output from the peak detection circuit 16 exceeds a threshold value. As shown in FIG. 5, the control circuit 17 is constructed by an operational amplifier 31, variable resistor VR, and resistors R21 and R22.

In the operational amplifier 31, a threshold voltage is input to the noninverting input terminal, and the output voltage from the peak detection circuit 16 is input to the inverting input terminal. In this case, the noninverting input terminal is connected to the output terminal of the variable resistor VR for dividing a power supply voltage Vcc and outputting it. The inverting input terminal is connected to the output from the peak detection circuit 16 through the resistor R21 and also to the output terminal of the operational amplifier 31 through the resistor R22.

The output terminal of the operational amplifier 31 is connected to the gate of the FET switch 18 and the pull-out signal output line 21 as the output terminal of the control circuit 17.

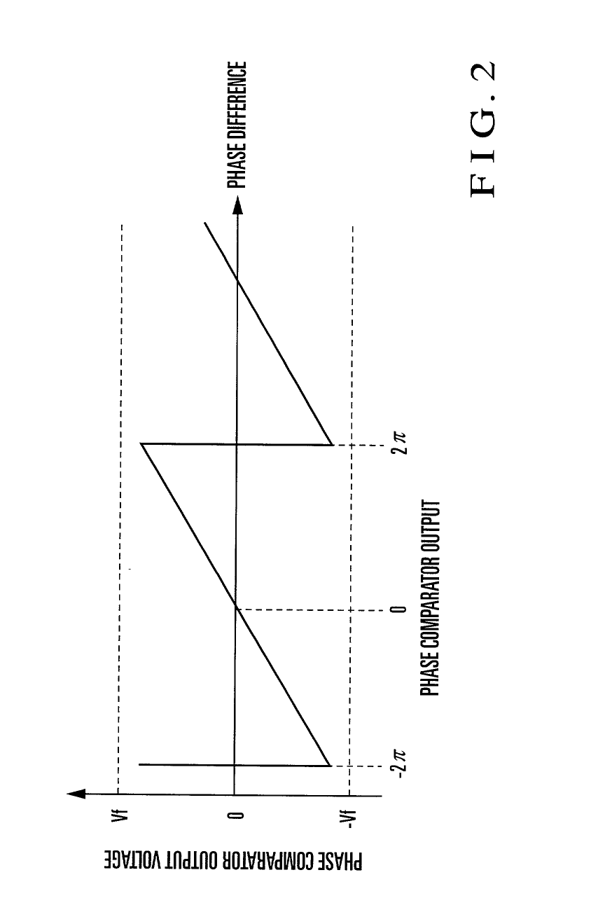

The operation of this PLL circuit will be described with reference to FIG. 1. In the locked state of the PLL circuit, the input data and the reference signal as the output from the VCO 13 are in phase, and the phase comparator 12 outputs no voltage, as shown in FIG. 2 (a point in the graph where the phase difference is 0). Hence, no VCO control voltage appears at the output of the lag-lead filter 14. Assume that the PLL circuit is in the pull-out state due to some reason. At this time, the phase comparator 12 outputs a voltage corresponding to the phase difference, as shown in FIG. 2. The output voltage acts to lower the oscillation frequency of the VCO 13 when the VCO 13 leads the input data in phase and raise the oscillation frequency of the VCO 13 when it has a phase lag. In this way, the phase-locked state is obtained again.

The time until the phase-locked state is obtained again is determined by a damping factor DF represented using time constants T₁ and T₂ of the lag-lead filter 14.

$$DF = \frac{1}{2} ( {T}_{2} + \frac{1}{k} ) \sqrt{\frac{k}{{T}_{1} + {T}_{2}}}$$

for

T₁=R11×C11

T₂=R12×C11

where R11, R12, and C11 are the resistors and capacitor of the lag-lead filter 14 shown in FIG. 1, respectively.

In addition,

K=Kp×Kv

where Kp is the gain of the phase comparator 12, and Kv is the gain of the VCO 13.

When the damping factor DF is large, the PLL circuit is stable, though the pull-in time (time required for re-lock) becomes long. Conversely, when the damping factor DF is small, high-speed pull-in can be realized. However, peaking or the like occurs in the frequency characteristics of the filter, resulting in inconvenience (the phase tone is amplified).

That is, when the damping factor DF can be largely changed only in the pull-out state, a PLL circuit capable of stable and high-speed pull-in operation can be realized.

As a variation factor supposed in control voltage of the VCO 13, the modulation sensitivity of the VCO 13 changes due to a variation in frequency of the input data or a change in ambient temperature. If the frequency of the input data abruptly changes, the control voltage of the VCO 13 largely varies to result in pull-out. When the modulation sensitivity of the VCO 13 changes due to a change in ambient temperature, the control voltage of the VCO 13 moderately varies following the moderate variation in ambient temperature while keeping the locked state.

In the present invention, when the control voltage of the VCO 13 abruptly changes over time as in the pull-out state, a large output appears at the output of the differentiating circuit 15. The peak detection circuit 16 detects the peak of the output voltage from the differentiating circuit 15. When the detected value exceeds a predetermined value, the control circuit 17 generates a signal to turn on the FET switch 18. When the FET switch 18 is ON, the resistor R11 is short-circuited. This makes the time constant T₁ of the lag-lead filter 14 small and the damping factor DF large. With this operation, the pull-in time can be shortened. The output signal from the control circuit 17 is output as a pull-out signal.

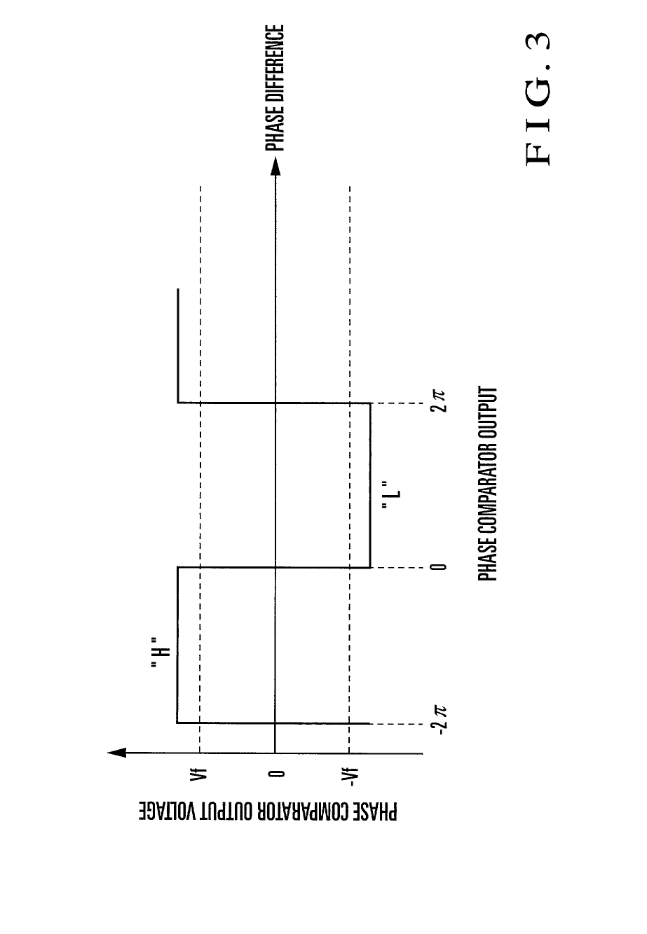

When pull-out is detected, the damping factor DF can be changed to shorten the pull-in time. The present invention can also be applied to a phase comparator of output type shown in FIG. 3.

The PLL circuit according to the present invention can be applied to an oscillation circuit, modulation circuit, demodulation circuit, frequency synthesizer, transmitter, receiver, transceiver, optical oscillation circuit, optical modulation circuit, optical demodulation circuit, or the like.

The PLL circuit can be incorporated in an IC chip.

The number, positions, and shapes of constituent elements are not limited to the above embodiment. The number, positions, and shapes suitable for implementation of the present invention can be employed.

The present invention with the above arrangement has the following effects.

1. Since the time constant of the lag-lead filter 14 as a loop filter can be changed independently of the waveform or magnitude of an output voltage of the phase comparator 12, the damping factor becomes large, and high-speed pull-in can be realized.

2. By detecting the temporal change in control voltage of the VCO 13, the pull-out state can be accurately detected.

What is claimed is:

1. A phase-locked loop circuit comprising:
a phase comparator for receiving input data and a reference signal and outputting a voltage value representing a phase difference between the input data and the reference signal;
a filter circuit for generating and outputting a control voltage on the basis of the voltage value representing the phase difference between the input data and the reference signal output from said phase comparator;
a voltage-controlled oscillator for generating the reference signal on the basis of the control voltage output from said filter circuit and outputting the reference signal to said phase comparator;
pull-out state detection means for outputting a signal representing a pull-out state when a change amount of the control voltage output from said filter circuit within a predetermined time exceeds a threshold value; and
short-circuit means for short-circuiting at least one of constituent elements of said filter circuit when the signal representing the pull-out state is output from said pull-out state detection means.

2. A circuit according to claim 1, wherein said pull-out state detection means comprises
a differentiating circuit for generating an output corresponding to the change amount of the control voltage output from said filter circuit within the predetermined time, and
pull-out signal output means for detecting the peak of an output from said differentiating circuit and outputting the signal representing the pull-out state when the detected peak value exceeds a predetermined value.

3. A circuit according to claim 2, wherein said pull-out signal output means comprises
a peak detection circuit for detecting the peak of the output from said differentiating circuit and holding and outputting the detected peak value, and
a control circuit for outputting the signal representing the pull-out state when an output from said peak detection circuit exceeds the threshold value.

4. A circuit according to claim 3, wherein said control circuit comprises a voltage comparator for outputting the signal representing the pull-out state when a voltage value of the output from said peak detection circuit exceeds the threshold value.

5. A circuit according to claim 1, wherein said pull-out state detection means has a pull-out signal output line for externally outputting the signal representing the pull-out state except to said short-circuit means.

6. A circuit according to claim 1, wherein said short-circuit means short-circuits a constituent element of said filter circuit, which increases a damping factor of said filter circuit upon being short-circuited.

7. A circuit according to claim 1, wherein said short-circuit means comprises a switching element which has a drain and source connected in parallel to a constituent element of said filter circuit, which increases a damping factor of said filter circuit upon being short-circuited, said switching element being turned on in accordance with the signal representing the pull-out state and input to a gate.

8. A circuit according to claim 7, wherein said switching element comprises an FET (Field Effect Transistor).

9. A circuit according to claim 1, wherein said short-circuit means short-circuits a resistor connected in series to an output from said phase comparator and an input to said voltage-controlled oscillator.

10. A circuit according to claim 1, wherein said filter circuit comprises a lag-lead filter.
